(19) United States
(12) Patent Application Publication
(10) Pub. No.: US 2017/0088951 A1
(43) Pub. Date: Mar. 30, 2017

(54) DEPOSITION OF HIGH-QUALITY MIXED OXIDE BARRIER FILMS

(71) Applicants: Eric R. Dickey, Hillsboro, OR (US); Bryan Larson Danforth, Portland, OR (US)

(72) Inventors: Eric R. Dickey, Hillsboro, OR (US); Bryan Larson Danforth, Portland, OR (US)

(21) Appl. No.: 14/885,750

(22) Filed: Oct. 16, 2015

Related U.S. Application Data
(60) Provisional application No. 62/065,477, filed on Oct. 17, 2014.

(51) Int. Cl. C23C 16/455; C23C 16/54; H01L 31/18; H01L 51/00; H01L 31/048; C23C 16/40; H01L 51/52

(52) U.S. Cl. CPC C23C 16/45542; C23C 16/45548; C23C 16/403; C23C 16/405; C23C 16/545; H01L 51/5253; H01L 51/0001; H01L 31/0481; H01L 31/186

(57) ABSTRACT

The present disclosure relates to metal oxide barrier films and particularly to methods for depositing high-quality barrier films. Methods are disclosed that are capable of producing thin barrier films with water vapor transmission rates (WVTR) below 0.1 g/(m²·day) after exposure to extreme temperatures and humidity. Methods are disclosed for making such films on a continuous web.

### CROSS-REFERENCE TO RELATED APPLICATIONS

Under 35 U.S.C. §119(e), this application claims the benefit of U.S. Provisional Patent Application No. 62/065,477, entitled “DEPOSITION OF HIGH-QUALITY MIXED OXIDE BARRIER FILMS,” filed Oct. 17, 2014, the contents of which are hereby incorporated herein by reference in their entirety.

### TECHNICAL FIELD

The present disclosure relates to metal oxide barrier films and particularly to methods for depositing high-quality mixed oxide barrier films.

### BACKGROUND

With the ever increasing concerns over global warming, there is a growing demand for affordable solar energy. Photovoltaic (PV) modules are used to capture solar energy and generate electrical energy. The PV modules are exposed to severe environmental temperature and humidity extremes throughout the life of the product. The PV modules comprise, among other components, a backsheet that solar cells are mounted on and an encapsulation film that covers the solar cells. The solar cells are highly moisture-sensitive. The backsheet and encapsulation film need to be made of materials that will not transfer water to the solar cell, even over an extended period of time. Likewise, organic light emitting diodes (OLED) are highly moisture-sensitive and need encapsulation films that will not transfer water to the OLED.

Atomic layer deposition (ALD) is similar to conventional chemical vapor deposition (CVD) processes but distinct in its self-limiting growth at the surface of the substrate on an atomic level. ALD processes are disclosed in U.S. Pat. No. 4,058,430. ALD is a process that generates thin films that are extremely conformal, highly dense, and provide pinhole-free coverage.

A need remains for an ALD process that could be used to produce high-quality barrier films, such as for PV modules and OLEDs.

### BRIEF DESCRIPTION OF THE DRAWINGS

FIG. 1 is similar to FIG. 1 of U.S. Pat. Nos. 8,137,464 and 8,202,366.

FIG. 2 is similar to FIG. 4 of U.S. Patent Publication No. 2012/0021128.

### DETAILED DESCRIPTION

The present disclosure relates to metal oxide barrier films and particularly to methods for depositing high-quality mixed oxide barrier films. Among other possible applications, the embodiments disclosed herein may be used to make high-quality barrier films. For example, the embodiments disclosed herein may potentially be used to make barrier films for PV modules and OLEDs.

In some embodiments of methods of making a mixed oxide barrier film on a substrate, the methods comprise exposing a portion of the substrate to one of a metal alkoxide or a metal-containing Lewis acid, exposing the same portion of the substrate to an oxygen-containing plasma, exposing the same portion of the substrate to the other of the metal alkoxide or the metal-containing Lewis acid, and exposing the same portion of the substrate again to an oxygen-containing plasma, to thereby form a mixed oxide barrier film, wherein all of the above steps are performed at a temperature less than 200° C.

In such embodiments, exposing a portion of the substrate to one of a metal alkoxide or a metal-containing Lewis acid comprises exposing the substrate to one of the metal alkoxide or the metal-containing Lewis acid in about five or less complete plasma-enabled atomic layer deposition (ALD) cycles before exposing the same portion of the substrate to the other one of the metal alkoxide or the metal-containing Lewis acid in a different complete plasma-enabled ALD cycle.

Furthermore, such embodiments may further comprise continuously transporting the substrate within an atomic layer deposition (ALD) reactor. For example, continuously transporting the substrate may comprise moving the substrate at a speed less than about 60 meters per minute (m/min), less than about 45 m/min, less than about 30 m/min, less than about 15 m/min, less than about 10 m/min, or less than about 5 m/min.

In a related example, continuously transporting the substrate may comprise moving the substrate as a web from a feed roll to an uptake roll. In such exemplary embodiments, the web may move back and forth between at least a first precursor zone, an isolation zone, and a second precursor zone within the ALD reactor, wherein exposing a portion of the substrate to one of a metal alkoxide or a metal-containing Lewis acid occurs in the first precursor zone, wherein exposing the same portion of the substrate to an oxygen-containing plasma occurs in the isolation zone, wherein exposing the same portion of the substrate to the other of the metal alkoxide or the metal-containing Lewis acid occurs in the second precursor zone, and wherein exposing the same portion of the substrate again to an oxygen-containing plasma occurs in the isolation zone. For example, the web may move back and forth in either a serpentine fashion or a spiral fashion between at least the first precursor zone, the isolation zone, and the second precursor zone within the ALD reactor.

In some of such embodiments, the exposing steps are performed at a temperature less than about 150° C. or less than about 100° C.

In some embodiments of methods of making a mixed oxide barrier film on a substrate, the method comprises exposing a portion of the substrate to one of a metal alkoxide or a metal-containing Lewis acid and then exposing the same portion of the substrate to an oxygen-containing plasma, thereby forming less than a monolayer of a first metal oxide sublayer in a first ALD cycle. The methods may further comprise exposing the same portion of the substrate to the other of the metal alkoxide or the metal-containing Lewis acid and exposing the same portion of the substrate again to an oxygen-containing plasma, thereby forming less than a monolayer of a second metal oxide sublayer in a second ALD cycle, wherein the first metal oxide is different from the second metal oxide. The methods may further comprise repeating the above sequence of steps multiple times at a temperature less than about 120° C., to thereby form a mixed oxide barrier film.

In some of such embodiments, the exposing steps are performed at a temperature less than about 100° C.

In some of such embodiments, the methods may further comprise continuously transporting the substrate within an atomic layer deposition (ALD) reactor. For example, continuously transporting the substrate may comprise moving the substrate at a speed less than about 60 meters per minute (m/min), less than about 45 m/min, less than about 30 m/min, less than about 15 m/min, less than about 10 m/min, or less than about 5 m/min.

Continuously transporting the substrate may comprise moving the substrate as a web from a feed roll to an uptake roll. In such exemplary embodiments, the web may move back and forth between at least a first precursor zone, an isolation zone, and a second precursor zone within the ALD reactor, wherein exposing a portion of the substrate to one of a metal alkoxide or a metalorganic occurs in the first precursor zone, wherein exposing the same portion of the substrate to an oxygen-containing plasma, thereby forming less than a monolayer of a first metal oxide sublayer occurs in the isolation zone, wherein exposing the same portion of the substrate to the other of the metal alkoxide or the metalorganic occurs in the second precursor zone, and wherein exposing the same portion of the substrate again to an oxygen-containing plasma, thereby forming less than a monolayer of a second metal oxide sublayer occurs in the isolation zone. For example, the web may move back and forth in either a serpentine fashion or a spiral fashion between at least the first precursor zone, the isolation zone, and the second precursor zone.

In some embodiments of methods of making a mixed oxide barrier film on a substrate, the methods comprise continuously transporting the substrate at a speed of less than about 60 meters per minute (m/min) within an atomic layer deposition (ALD) reactor. The methods may further comprise exposing a portion of the substrate to one of a metal alkoxide or a metal-containing Lewis acid, exposing the same portion of the substrate to an oxygen-containing plasma, exposing the same portion of the substrate to the other of the metal alkoxide or the metal-containing Lewis acid, and exposing the same portion of the substrate again to an oxygen-containing plasma, to thereby form a barrier film.

In such embodiments, exposing a portion of the substrate to one of a metal alkoxide or a metal-containing Lewis acid may comprise exposing the substrate to one of the metal alkoxide or the metal-containing Lewis acid in about five or less complete plasma-enabled atomic layer deposition (ALD) cycles before exposing the same portion of the substrate to the other one of the metal alkoxide or the metal-containing Lewis acid in a different complete plasma-enabled ALD cycle.

Continuously transporting the substrate may comprise moving the substrate as a web from a feed roll to an uptake roll. In such exemplary embodiments, the web may move back and forth between at least a first precursor zone, an isolation zone, and a second precursor zone within the ALD reactor, wherein exposing a portion of the substrate to one of a metal alkoxide or a metal-containing Lewis acid occurs in the first precursor zone, wherein exposing the same portion of the substrate to an oxygen-containing plasma occurs in the isolation zone, wherein exposing the same portion of the substrate to the other of the metal alkoxide or the metal-containing Lewis acid occurs in the second precursor zone, and wherein exposing the same portion of the substrate again to an oxygen-containing plasma occurs in the isolation zone. For example, the web may move back and forth in either a serpentine fashion or a spiral fashion between at least the first precursor zone, the isolation zone, and the second precursor zone within the ALD reactor.

Some of such embodiments may further comprise continuously transporting the substrate at a speed less than about 45 m/min, less than about 30 m/min, less than about 15 m/min, less than about 10 m/min, or less than about 5 m/min.

In some of such embodiments, the exposing steps are performed at a temperature less than about 200° C., less than about 150° C., or less than about 100° C.

In any of the foregoing embodiments, the metal alkoxide may comprise an isopropoxide. In any of the foregoing embodiments, the metal alkoxide may comprise a titanium alkoxide. In any of the foregoing embodiments, the metal alkoxide may comprise titanium isopropoxide (TTIP). The TTIP may comprise at least about 3% impurities, at least about 2% impurities, or at least about 1% impurities.

In any of the foregoing embodiments, the metal-containing Lewis acid may comprise a metalorganic (e.g., trimethylaluminum (TMA)) or a metal halide (e.g., aluminum chloride). The TMA may comprise at least about 2% impurities or at least about 1% impurities.

In any of the foregoing embodiments, the precursors may or may not be semiconductor-grade precursors.

In any of the foregoing embodiments, the source gas for the oxygen-containing plasma may comprise oxygen-containing molecules that minimize the generation of ozone, such as, for example, carbon dioxide, nitric oxide, nitrogen dioxide, and combinations thereof. The source gas may include nitrogen (N₂) and may include significant amounts of nitrogen. The source gas may have less than about 0.01% impurities.

In any of the foregoing embodiments, the mixed oxide barrier film may comprise alumina and titania. In some of such embodiments, there may be no detectable sublayers of alumina or titania in the mixed oxide barrier film when viewed by transmission electron microscopy. For example, the mixed oxide barrier film may comprise an essentially homogeneous TiAlₓO_{y} phase.

In any of the foregoing embodiments, the substrate may comprise a flexible film. Exemplary flexible films include polyethylene terephthalate, polypropylene, biaxially-oriented polypropylene, polyetheretherketone, polyimide, and polyethylene naphthalate.

In any of the foregoing embodiments, the barrier film may have a thickness of less than about 50 nm and a water vapor transmission rate (WVTR) of less than 0.1 g/(m²·day) after exposure to a pressure cooker test. In some of such embodiments, the barrier film has a thickness of less than about 40 nm, less than about 35 nm, less than about 30 nm, less than about 25 nm, or less than about 20 nm, while having a WVTR of less than 0.1 g/(m²·day) after exposure to a pressure cooker test. The pressure cooker test may comprise testing the barrier film at a temperature of 105° C., 100% relative humidity, and at a pressure equal to saturation water vapor pressure (about 916 torr) for 96 hours. Additionally, at any of the above thicknesses, the barrier film may have a WVTR of less than about 0.001 g/(m²·day) or less than about 0.0005 g/(m²·day), such as per ASTM-1249, before the pressure cooker test. One example of a pressure cooker test is described in Example 1. A pressure cooker test may be performed according to IEC Pub. 60068-2-66.

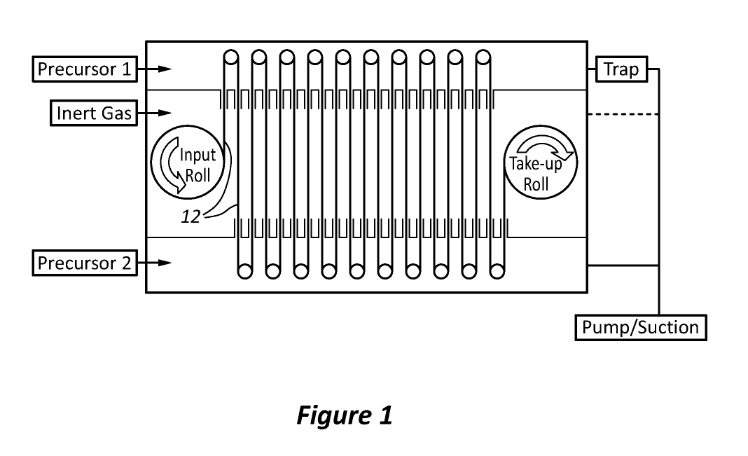

U.S. Pat. Nos. 8,137,464 and 8,202,366, the contents of both of which are incorporated herein by reference in their entirety, disclose embodiments of roll-to-roll plasma-enabled ALD reactors that may be used in the embodiments disclosed herein. FIG. 1 is similar to FIG. 1 of U.S. Pat. Nos. 8,137,464 and 8,202,366. In one example of how the embodiments of U.S. Pat. Nos. 8,137,464 and 8,202,366 could be used with the embodiments disclosed herein, Precursor 1 and Precursor 2 of FIG. 1 could be TTIP and TMA, respectively, or vice versa. Likewise, the Inert Gas (i.e., source gas for plasma) could be nitrogen and carbon dioxide and a plasma generated in the isolation zone between the precursor zones (not illustrated). The flexible substrate 12 could be continuously transported at a speed of less than about 60 m/min. The temperature of the reaction chamber could be maintained at about 100° C. or less. Other examples from U.S. Pat. Nos. 8,137,464 and 8,202,366 could likewise apply to the embodiments disclosed herein.

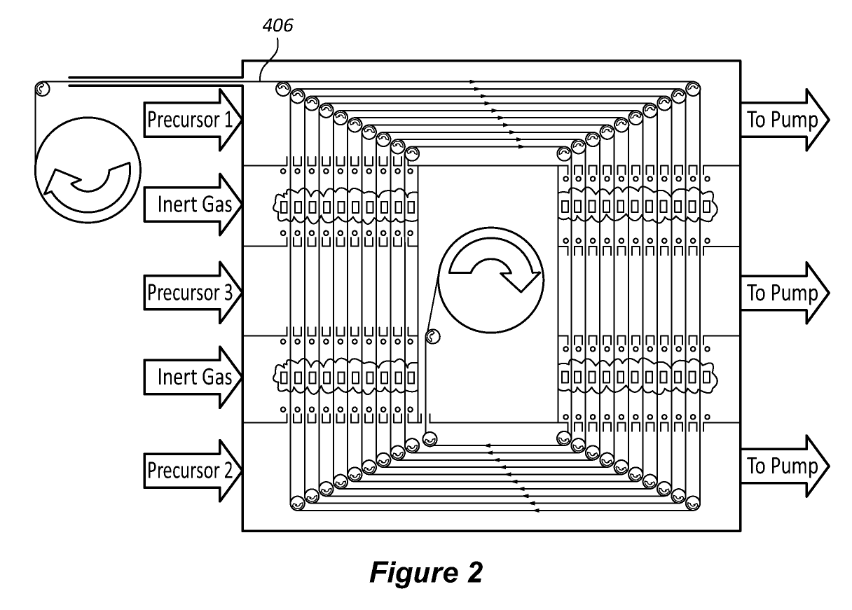

U.S. Patent Application Publication No. 2012/0021128, the contents of which are incorporated herein by reference in their entirety, discloses embodiments of roll-to-roll plasma-enabled ALD reactors that could be used in the embodiments disclosed herein. FIG. 2 is similar to FIG. 4 of U.S. Patent Application Publication No. 2012/0021128. In one example of how the embodiments of U.S. Patent Publication No. 2012/0021128 could be used with the embodiments disclosed herein, Precursor 1 and Precursor 2 of FIG. 2 could both be TTIP and Precursor 3 could be TMA (alternatively, Precursor 1 and Precursor 2 could be TMA and Precursor 3 could be TTIP). The Inert Gas could be nitrogen and carbon dioxide (i.e., source gas for plasma) and a plasma generated in the isolation zone between the precursor zones (illustrated as clouds). Plasma generations in an isolation zone, and other alternatives, are disclosed in more detail in U.S. Patent Application Publication No. 2012/0021128. The substrate 406 could be continuously transported at a speed of less than about 60 m/min. The temperature of the reaction chamber could be maintained at about 100° C. or less. Other examples from U.S. Patent Publication No. 2012/0021128 could likewise apply to the embodiments disclosed herein.

### Example 1

Solar panels need to pass environmental tests per International Electrotechnical Commission (IEC) and United Laboratories (UL) requirements to prove their durability. In the solar industry, environmental tests, so-called “damp heat tests,” are commonly performed at 85° C. and 85% relative humidity (RH) for 2,000 to 3,000 hours. These tests are set not only for solar panels but also for components such as encapsulating barrier films and backsheets. Before conducting 2,000- to 3,000-hour damp heat tests, pressure cooker tests (PCT) may be conducted as an accelerated test to determine whether a sample is likely to perform well during the longer damp heat tests. PCT may be conducted in a high-temperature and high-humidity controlled chamber, such as at 105° C. and 100% RH at water vapor saturation pressure (about 916 torr at such a temperature) for 96 hours.

Two different PCT tests were conducted, Test 1 and Test 2. In each test, barrier films were made using a system similar to the system 10 illustrated in FIG. 1. For both tests, trimethylaluminum (TMA), 99.99% pure, was introduced into the top zone. For Test 1, titanium tetraisopropoxide (TTIP), 99.99% pure, was introduced into the bottom zone. For Test 2, titanium tetrachloride (TiCl₄), 99.99% pure, was introduced into the bottom zone. For both tests, the deposition chamber was isotropically heated to 100° C. For both tests, the substrate was DuPont Melinex® ST-504 PET web, about 125 microns thick. There was no O₂ pretreatment of the substrate. For both tests, the source gas (Inert Gas, FIG. 1) for the plasma was 5.3 standard liters per minute (SLM) N₂ and 1.4 SLM CO₂. For both tests, input power was in current constant mode at 20.20 A (424-428 V) with a setpoint of 20.20 A. For both tests, the substrate web speed was 30 m/min. For both tests, the substrate was run through the deposition chamber three consecutive times (i.e., taken up by the take-up roll and then run through the deposition chamber again). The thickness of the resulting films was determined by ellipsometry.

Water vapor transmission rate (WVTR) was measured using two different instruments during the study. The films were first measured pursuant to ASTM-1249 on an Illinois Instruments Water Vapor Transmission Analyzer Model 7001 with a detection limit specified at 3×10⁻³ g/(m²·day). When the films measured below this detection limit, additional tests were run pursuant to ASTM-1249 using a MOCON Aquatran analyzer with a sensitivity range specified at 5×10⁻⁴ g/(m²·day).

The plasma cleaned films were individually laminated with hydrolysis-resistant polyethylene terephthalate (PET), 2 mil thick (about 50 microns). Prior to lamination, the films of Test 1 and Test 2 were exposed to glow discharge inductively coupled plasma, N₂ gas at 100 sccm, a pressure of 115 mTorr, and radio frequency of 13.56 MHz, for 30 seconds to clean the surfaces. As part of the lamination process, the hydrolysis-resistant PET was corona discharge treated at 3.3 A, 130 V, for four passes at 15 m/min, with a CG-102 power source (Kasuga Co. Ltd). A urethane-type adhesive was applied, about dry weight 10-15 g/m², with a bar coater (#12 wire wound rod bar, R.D. Specialties, Webster, N.Y.) to the corona discharge treated surface of a hydrolysis-resistant PET. The adhesive coated PET was dried in a dry air oven at 75° C. for one minute. After drying the adhesive, the test films were applied face-down to the adhesive coated PET with a roller laminator to form laminated test pieces. The laminated test pieces were kept at 60° C. for 48 hours to complete adhesive curing. The laminated test pieces consisted of an about 125 micron thick DuPont Melinex® ST-504 PET substrate, the respective mixed oxide test film, the adhesive layer, and the about 50 micron thick hydrolysis-resistant PET.

Next, the PCT was performed. Each laminated test piece was placed on its own copper plate with the ST-505 PET outer surface face-down. The laminated test pieces were held in place with polyimide tape. The copper plate was placed vertically in a pressure cooker tester (EHS211MD model, ESPEC Co., Ltd.). The pressure cooker tester was then heated to 105° C. at 100% RH for either 24 hours or 96 hours at about 916 torr and the WVTR determined by the instrument.

The test results are shown in Table 1 below.

TABLE 1

| | | | | | Thick- | Web | | WVTR | WVTR |
|---|---|---|---|---|---|---|---|---|---|
| | Prec. | Prec. | Plasma | Temp | ness | speed | WVTR | PCT24 | PCT96 |
| Test | 1 | 2 | Gas | ° C. | nm | m/min | g/(m² · d) | g/(m² · d) | g/(m² · d) |
| 1 | TTIP | TMA | N₂:CO₂ | 100 | 18.4 | 30 | <5 × 10⁻⁴ | | 8.5 × 10⁻² |
| 2 | TiCl₄ | TMA | N₂:CO₂ | 75 | 20 | 30 | <5 × 10⁻⁴ | 1.6 | |

It will be apparent to those having skill in the art that many changes may be made to the details of the above-described embodiments and examples without departing from the underlying principles of the invention.

1. A method of making a mixed oxide barrier film on a substrate, the method comprising:
exposing a portion of the substrate to one of a metal alkoxide or a metal-containing Lewis acid;
exposing the same portion of the substrate to an oxygen-containing plasma;
exposing the same portion of the substrate to the other of the metal alkoxide or the metal-containing Lewis acid; and
exposing the same portion of the substrate again to an oxygen-containing plasma, to thereby form a mixed oxide barrier film, wherein all of the above steps are performed at a temperature less than 200° C.

2. The method of claim 1, wherein the metal alkoxide comprises titanium isopropoxide (TTIP).

3. The method of claim 1, wherein the metal-containing Lewis acid comprises a metalorganic or a metal halide.

4. The method of claim 3, wherein the metal halide comprises aluminum chloride.

5. The method of claim 3, wherein the metalorganic comprises trimethylaluminum (TMA).

6. The method of claim 1, wherein a source gas for the oxygen-containing plasma comprises carbon dioxide, nitric oxide, nitrogen dioxide, or combinations thereof.

7. The method of claim 1, wherein the mixed oxide barrier film comprises alumina and titania.

8. The method of claim 1, wherein exposing a portion of the substrate to one of a metal alkoxide or a metal-containing Lewis acid comprises exposing the substrate to one of the metal alkoxide or the metal-containing Lewis acid in about five or fewer complete plasma-enabled atomic layer deposition (ALD) cycles before exposing the same portion of the substrate to the other one of the metal alkoxide or the metal-containing Lewis acid in a different complete plasma-enabled ALD cycle.

9. The method of claim 1, wherein the substrate comprises a flexible film.

10. The method of claim 1, further comprising continuously transporting the substrate within an atomic layer deposition (ALD) reactor.

11. The method of claim 1, wherein the barrier film has a thickness of less than about 50 nm and a water vapor transmission rate (WVTR) of less than about 0.1 g/(m²·day) after exposure to a pressure cooker test.

12. The method of claim 1, wherein the temperature is less than about 100° C.

13. A method of making a mixed oxide barrier film on a substrate, the method comprising:
exposing a portion of the substrate to one of a metal alkoxide or a metalorganic;
exposing the same portion of the substrate to an oxygen-containing plasma, thereby forming less than a monolayer of a first metal oxide sublayer in a first atomic layer deposition (ALD) cycle;
exposing the same portion of the substrate to the other of the metal alkoxide or the metalorganic;
exposing the same portion of the substrate again to an oxygen-containing plasma, thereby forming less than a monolayer of a second metal oxide sublayer in a second ALD cycle, wherein the first metal oxide is different from the second metal oxide; and
repeating the above sequence of steps multiple times at a temperature less than about 120° C., to thereby form a mixed oxide barrier film.

14. The method of claim 13, wherein the barrier film has a thickness of less than about 50 nm and a water vapor transmission rate (WVTR) of less than about 0.1 g/(m²·day) after exposure to a pressure cooker test.

15. The method of claim 14, wherein the barrier film has a thickness of less than about 20 nm.

16. The method of claim 14, wherein the barrier film has a WVTR of less than about 0.0005 g/(m²·day) before the pressure cooker test.

17. A method of making a mixed oxide barrier film on a substrate, the method comprising:
continuously transporting the substrate at a speed of less than about 60 meters per minute (m/min) within an atomic layer deposition (ALD) reactor;
exposing a portion of the substrate to one of a metal alkoxide or a metal-containing Lewis acid;
exposing the same portion of the substrate to an oxygen-containing plasma;
exposing the same portion of the substrate to the other of the metal alkoxide or the metal-containing Lewis acid; and
exposing the same portion of the substrate again to an oxygen-containing plasma, to thereby form a barrier film.

18. The method of claim 17, further comprising continuously transporting the substrate at a speed less than about 5 m/min.

19. The method of claim 17, wherein continuously transporting the substrate comprises moving the substrate as a web from a feed roll to an uptake roll.

20. The method of claim 19, wherein the web moves back and forth between at least a first precursor zone, an isolation zone, and a second precursor zone within the ALD reactor, wherein exposing a portion of the substrate to one of a metal alkoxide or a metal-containing Lewis acid occurs in the first precursor zone, wherein exposing the same portion of the substrate to an oxygen-containing plasma occurs in the isolation zone, wherein exposing the same portion of the substrate to the other of the metal alkoxide or the metal-containing Lewis acid occurs in the second precursor zone, and wherein exposing the same portion of the substrate again to an oxygen-containing plasma occurs in the isolation zone.
